(19) United States
(12) Patent Application Publication
(10) Pub. No.: US 2006/0016547 A1
(43) Pub. Date: Jan. 26, 2006

(54) System and method for transferring structured material to a substrate

(76) Inventors: Chien-Hua Chen, Corvallis, OR (US); James McKinnell, Salem, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/897,234

(22) Filed: Jul. 22, 2004

(51) Int. Cl. H01L 21/00

(52) U.S. Cl. 156/230; 438/50

(57) ABSTRACT

A structured material is transferred to a substrate. A release film is applied to a carrier. A material is deposited on a surface of the release film. The material is processed to form the structured material. The structured material is coupled to the substrate. The release film is exposed to reduce adhesion strength between the release film and the carrier, and the carrier and the release film are removed from the structured material.

### BACKGROUND

Micro-electromechanical system (“MEMS”) fabrication and packaging technology presents certain challenges to the manufacturing industry. For example, MEMS fabrication technology borrows from integrated circuit (“IC”) fabrication techniques, thus adding complexity and requirements to the MEMS packaging process. A MEMS device constructed on a first substrate using these techniques may, for example, require encapsulation in a hermetically sealed chamber to provide a protected and controlled operational environment. A second substrate is typically bonded to the first substrate, encapsulating the MEMS device, by using a bond material (e.g., solder) that mates with both substrates. Where placement accuracy or dimensional control of the bond material is not required, commercially available solder pre-forms may be used as the bond material. Where placement accuracy or dimensional control of the bond material is required, the bond material may be custom formed on one substrate by screen printing or plating processes.

A getter material may also require precision application. The getter material is a compound included within the hermetically sealed chamber to absorb (get) gases, liquids and solids, thereby preventing the gases, liquids or solids from interfering with operation of the MEMS device within the chamber. In one example, a moisture getter uses a compound that absorbs and binds water molecules. The getter material should not cause contamination within the hermetically sealed chamber.

The application of the getter material to a package containing a MEMS device is a critical process. Getter material applied to the wrong location results in device shorting, contamination or stiction problems, for example. Stiction is a friction problem where parts stick together, making the device inoperable. In a MEMS device that includes micro-motors and micro-gears, stiction may require high starting forces. In an accelerometer, for example, stiction may make the accelerometer inoperable. In addition, deposition of getter material after creation of parts forming the micro-motors and micro-gears may contaminate the parts and result in stiction.

Where an encapsulation contains two or more MEMS devices, one or more MEMS devices may be formed on each of two substrates that are bonded together to create the hermetically sealed chamber and encapsulate the MEMS devices. In this encapsulation, integration of bond material and getter material requires special consideration. For example, if the bond and getter material are deposited prior to recording media or micro-mover processes that create the MEMS device, the topography of the bond material can cause problems with photolithography processes and the getter material may be destroyed during a subsequent etching process. In another example, if the bond and/or getter material are deposited after recording media or micro-mover processes, material compatibility and contamination concerns increase; that is, the bond and/or getter material may contaminate or damage the MEMS device (including recording media film) during the deposition and/or etching processes.

The packaging process for the MEMS device is therefore critical to product reliability and longevity. It is desirable to accurately place the bond and/or getter material after creating the MEMS device, but during the packaging process, without damaging or contaminating the MEMS device. It is also desirable to encapsulate multiple MEMS devices at the wafer level to facilitate batch processing.

### SUMMARY OF THE INVENTION

The present disclosure advances the art by providing a system and method for transferring a structured material to a substrate.

In particular and by way of example only, according to an embodiment hereof, a method transfers a structured material to a substrate. A release film is applied to a carrier. A material is deposited on a surface of the release film. The material is processed to form the structured material. The structured material is coupled to the substrate. The release film is exposed to reduce adhesion strength between the release film and the carrier, and the carrier and the release film are removed from the structured material.

### BRIEF DESCRIPTION OF THE FIGURES

FIG. 1 shows a transparent carrier coated with an ultraviolet (“UV”) release film.

FIG. 2 shows a bond material deposited onto the transparent carrier and the UV release film of FIG. 1.

FIG. 3 shows the transparent carrier, UV release film and bond material after patterning and etching to form the structured material.

FIG. 4 shows a substrate with two previously created MEMS devices and coupled to the structured material.

FIG. 5 illustrates application of UV light to the exposed side of the transparent carrier of FIG. 4.

FIG. 6A shows the transparent carrier being removed from the UV release film.

FIG. 6B shows the transparent carrier and the UV release film being removed from the structured material.

FIG. 7A shows the substrate, the MEMS devices, and the structured material after the UV release film is removed.

FIG. 7B shows a top view of the substrate, one MEMS device, and the structured material of FIG. 7A.

FIG. 8 shows two substrates, bonded together at the structured material, to hermetically seal chambers containing MEMS devices.

FIG. 9 is a flowchart illustrating one exemplary process for attaching a structured material to a substrate that contains MEMS devices.

### DETAILED DESCRIPTION OF THE FIGURES

Before proceeding with the detailed description, it is to be appreciated that the present teaching is by way of example, not limitation. Thus, although the instrumentalities described herein are for the convenience of explanation, shown and described with respect to exemplary embodiments, it will be appreciated that the principals herein may be equally applied in other types of systems and methods for transferring a structured material to a substrate. Further, it will be appreciated that the described methods need not be performed in the order herein described, but that this description is merely exemplary of at least one system and method for transferring a structured material to a substrate.

Turning now to the figures, a precision structure transfer technique is described to transfer a structured material (e.g., a structured bond material or a structured getter material) to a substrate in a micro-electromechanical system (“MEMS”) packaging process. The structured material is first created on a carrier such that it may be accurately positioned on a receiving surface.

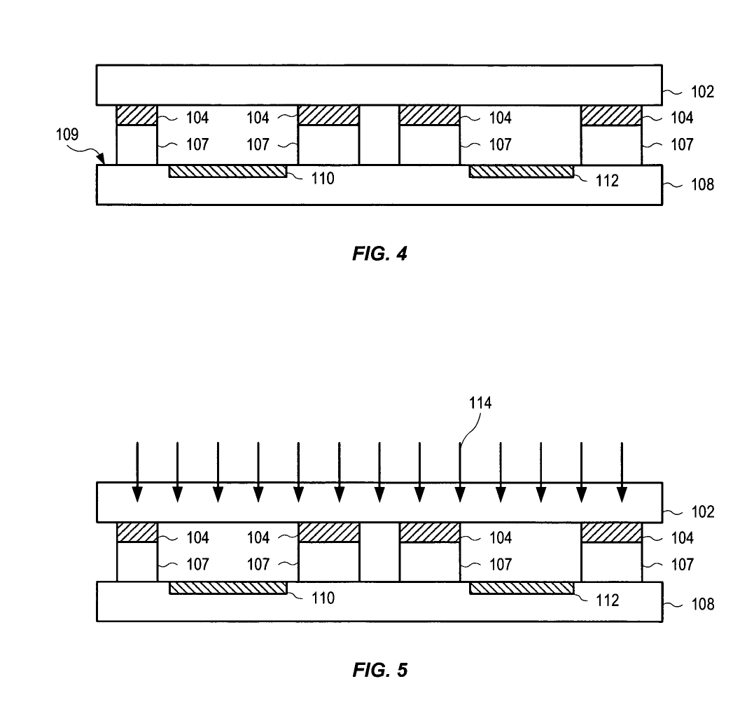

The following example illustrates one structure transfer technique that transfers a structured bond material 107 (FIG. 3) to a surface 109 of a substrate 108 (FIG. 4). Substrate 108 is, for example, a silicon substrate. Bond material 107 is, for example, a polymer or other organic compound. Upon reading and fully understanding this disclosure, one skilled in the art should appreciate that other materials may also be accurately structured and transferred to other surfaces using the following technique; for example, a getter material may be similarly structured and transferred to a substrate in a MEMS packaging process.

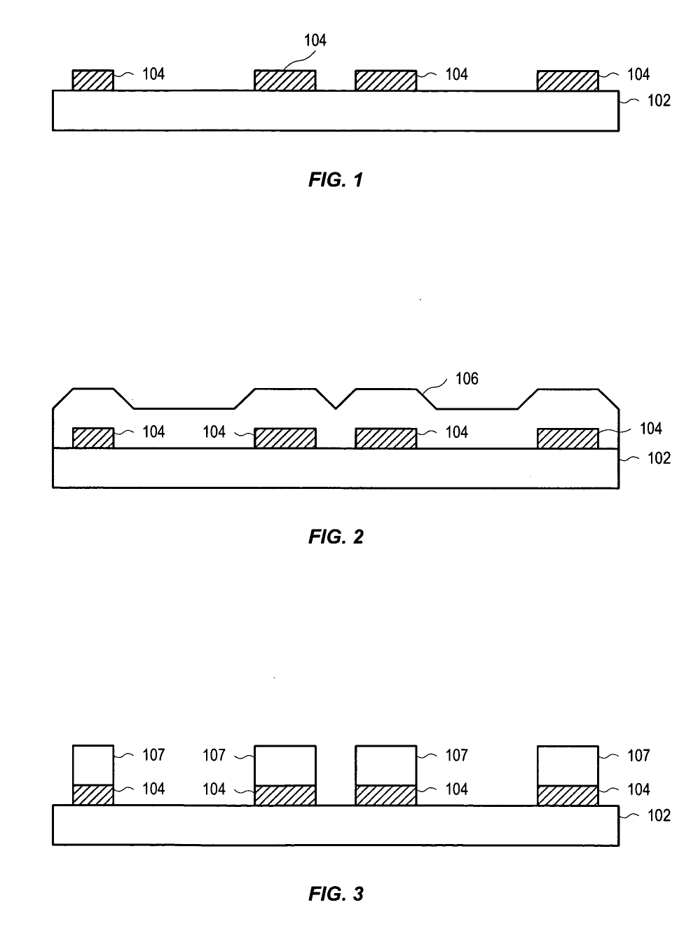

In particular, FIG. 1 shows a transparent carrier 102 coated with an ultraviolet (“UV”) release film 104. Transparent carrier 102 is, for example, a glass substrate with a coefficient of thermal expansion (“CTE”) closely matched, in this example, to the CTE of substrate 108.

UV release film 104 may be applied to transparent carrier 102 using a lamination process, though other processes may be used, such as a ‘spin coat’ process. A patterning and etching process may be used to pattern UV release film 104, as shown in FIG. 1, to match desired bond or getter patterns. However, UV release film 104 need not be patterned.

FIG. 2 shows a bond material 106 deposited onto UV release film 104 and transparent carrier 102 to form a coating of uniform thickness. Bond material 106 is then patterned and etched, for example by patterning and etching processes, to leave transparent carrier 102 with a structured bond material 107 and UV release film 104, as shown in FIG. 3. These patterning and etching processes provide accurate shaping of bond material 106 into structured bond material 107, as shown. U.S. Pat. No. 3,940,288 describes one such patterning and etching process and is incorporated herein by reference.

FIG. 4 shows a substrate 108 with two previously created MEMS devices 110 and 112 coupled to structured bond material 107. Transparent carrier 102, UV release film 104 and structured bond material 107 are positioned to mate with substrate 108, as shown in FIG. 4, such that structured bond material 107 does not contaminate MEMS devices 110 and 112. Patterning and/or etching process may for example accurately define known size and locations of UV release film 104 and structure bond material 107 to avoid the contamination. In an exemplary embodiment, structured bond material 107 attaches to substrate 108 through an aligned tacking process. In this example, an aligner aligns transparent carrier 102 to substrate 108 and bond material 107 is tacked to substrate 108 by solder or compression bonding.

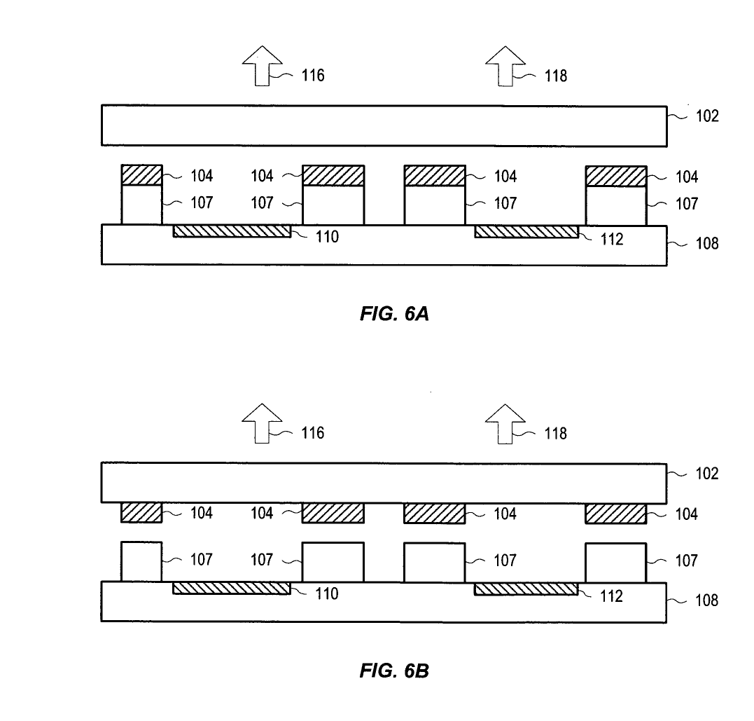

FIG. 5 illustrates UV light 114 being applied to transparent carrier 102. UV light 114 passes through transparent carrier 102 and reduces the adhesive strength of UV release film 104. In one embodiment, the adhesive strength between UV release film 104 and transparent carrier 102 is reduced such that adhesive strength between structured bond material 107 and substrate 108 is greater than the adhesive strength between UV release film 104 and transparent carrier 102. The reduced adhesion strength of UV release film 104 to transparent carrier 102 allows removal of transparent carrier 102, indicated by arrows 116, 118 in FIG. 6A.

As shown in FIG. 6A, at least a portion of UV release film 104 may remain attached to structured bond material 107, as shown, and may be removed, for example, by an ashing technique in a plasma chamber. U.S. Pat. No. 4,017,404 describes one such ashing technique and is incorporated herein by reference.

Alternatively, in another embodiment, after exposing UV release film 104 to UV light through transparent carrier 102 (FIG. 5), adhesion strength between UV release film 104 and structured bond material 107 is reduced such that adhesion strength between transparent carrier 102 and UV release film 104 is greater than adhesion strength between UV release film 104 and structured bond material 107. The reduced adhesion strength of UV release film 104 to structured bond material 107 allows removal of transparent carrier 102 and structured UV release film 104, indicated by arrows 116, 118 in FIG. 6B. Moreover, in at least one embodiment, substantially all UV release film 104 is removed from structured bond material 107 as transparent carrier 102 is lifted away.

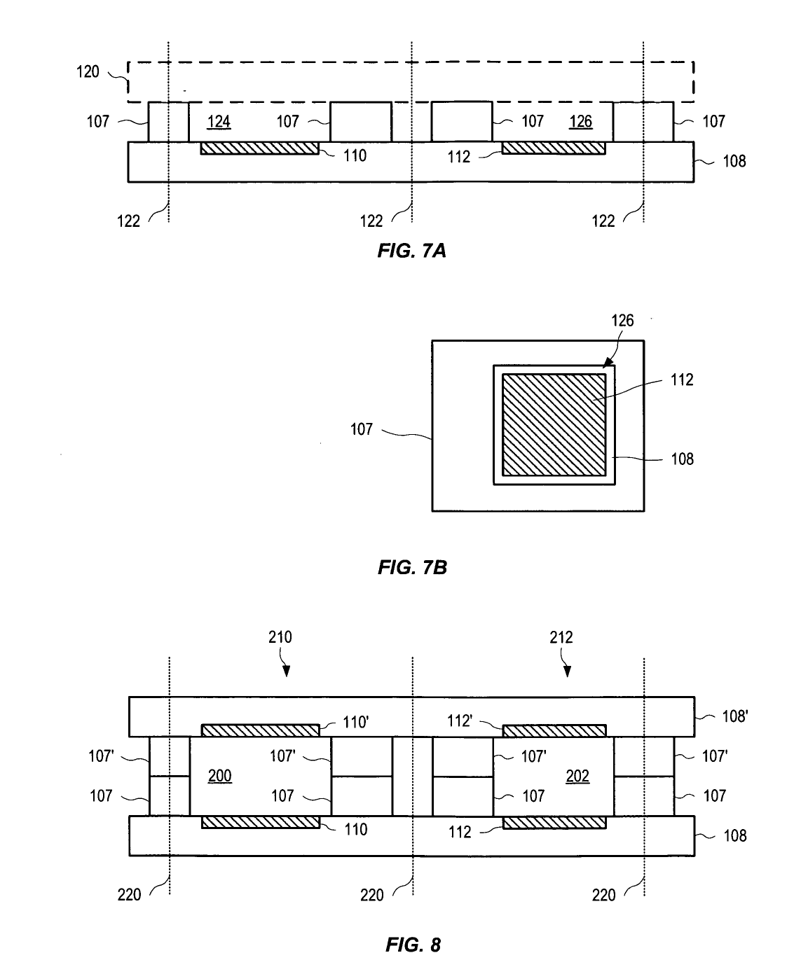

Accordingly, structured bond material 107 may be accurately applied to substrate 108 without damage to, interference with, or contamination of, MEMS devices 110 and 112, as shown in FIG. 7A; this application may be advantageously achieved without requiring MEMS devices 110 and 112 to endure additional patterning and etching processes.

By coupling another substrate (or lid) 120 (shown in dotted outline) to structured bond material 107, the resulting structure may be singulated to form multiple MEMS-encapsulated packages. By way of example, by separating this structure at dotted lines 122, two separate packages result when (a) a hermetically sealed chamber 124 forms between substrates 108, 120 to encapsulate MEMS device 110 and (b) a hermetically sealed chamber 126 forms between substrates 108, 120 to encapsulate MEMS device 112.

FIG. 7B shows a top view of substrate 108, MEMS device 112, and structured material 107 to illustrate chamber 126; FIG. 7B is shown without substrate 120 for purposes of illustration. As shown, MEMS device 112 is nested within chamber 126 such that structured material 107 does not contaminate or interfere with MEMS device 112. As is illustrated, structured material 107 is not in direct physical contact with MEMS device 112, a condition which may or may not be desired in actual fabrication processes, but which is illustrated here for purposes of discussion.

FIG. 8 shows a second substrate 108′, which contains MEMS devices 110′ and 112′ and a structured bond material 107′, positioned to mate with structured bond material 107 of substrate 108. Structured bond material 107′ may be transferred to second substrate 108′ using the structure transfer technique described above. Second substrate 108′ is bonded to substrate 108 by structured bond materials 107 and 107′ to form chambers 200 and 202, as shown. Chamber 200 encapsulates MEMS devices 110 and 110′ and chamber 202 encapsulates MEMS devices 112 and 112′. Chambers 200 and 202 are thus constructed without exposing MEMS devices 110, 110′, 112 and 112′ to a bond material (e.g., bond material 106) via a deposition process; this provides greater reliability of operation of MEMS devices 110, 110′, 112 and 112′. Again, singulation may be used to separate MEMS devices 110, 110′, 112 and 112′ into separate packages 210, 212, such as by separating these packages at dotted lines 220.

The structure transfer technique described above is, for example, suited to wafer level production of MEMS devices since placement accuracy of structured bond material 107 reduces risk of damage to fabricated MEMS devices while permitting wafer level processing. MEMS devices may thus be encapsulated at a wafer level prior to singulation (i.e., sawing of the devices from the wafer), thereby reducing risk of damage during singulation.

Getter materials may similarly be attached to substrates 108 and 108′ using the above described structure transfer technique, to reduce risk of contamination or damage to MEMS devices 110, 110′, 112 and 112′. The getter materials may be patterned and etched independently of substrate 108, for example.

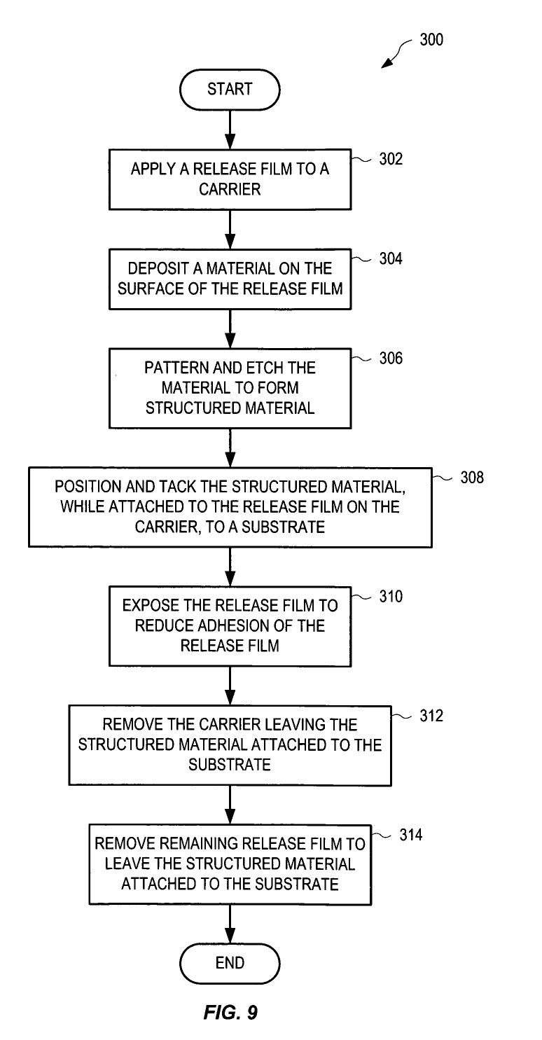

FIG. 9 is a flowchart illustrating one exemplary structure transfer process 300 that transfers a structured material (e.g., structured bond material 107) to a substrate (e.g., substrate 108). In step 302, process 300 applies a release film (e.g., UV release film 104) to a transparent carrier (e.g., transparent carrier 102), such as shown in FIG. 1. In step 304, process 300 deposits a material (e.g., a getter material or bond material 106) onto the surface of the release film, such as shown in FIG. 2. In step 306, process 300 patterns and etches the material to produce structured material. In one example of step 306, bond material 106 is formed into structured bond material 107 that is shaped to match desired bonding locations on a substrate (e.g., substrate 108), such as shown in FIG. 3.

In step 308, process 300 positions and tacks the structured material onto the substrate while the structured material is still attached to the transparent carrier by the release film, such as shown in FIG. 4. In step 310, process 300 exposes the release film to reduce the adhesive strength of the release film, such as shown in FIG. 5. Examples of step 310 are illustrated and described in connection with FIG. 5, FIG. 6A and FIG. 6B. In step 312, process 300 removes the transparent carrier from the release film to leave the structured material attached to the substrate, such as shown in FIG. 6A. The release film may remain attached to the structured material, such as shown in FIG. 6A, after separation from the transparent carrier. In step 314, process 300 removes (e.g., ashes) remaining release film (e.g., by placing the substrate in a plasma chamber) to leave the structured material attached to the substrate, such as shown in FIG. 7A.

In an alternative embodiment of process 300, the release film may remain attached to the transparent carrier, as shown in FIG. 6B; in this case, step 314 may be skipped.

The structured material may thus be accurately shaped and positioned on the substrate without contamination or damage to MEMS devices (e.g., devices 110 and 112). Further, since the structured material is produced by the patterning and etching process described in step 306, precision placement may be achieved, resulting in higher yields by increasing MEMS device density on each wafer. Since the deposition process of step 304 and patterning and etching processes of step 306 are applied to the transparent carrier, and do not involve the substrate, the MEMS devices are not subjected to these additional processes during device packaging.

Using process 300, assembly and packaging processes may be separated from the MEMS fabrication processes, removing complications that arise when two substrates containing MEMS devices are joined, such as shown in FIG. 8.

In the above description, MEMS devices 110, 112, 110′ and 112′ may for example be tiny (e.g., micro- or nano-sized) actuators, motors, gears and/or sensors.

Changes may be made in the above methods and systems without departing from the scope hereof. For example, in one alternate embodiment, a polymer adhesive film is applied to transparent carrier 102 in place of UV release film 104. The structured material is then formed (for example using the above-described processes) on the polymer adhesive and positioned and tacked to substrate 108. Laser light may be used in place of UV light 114 to ablate the polymer adhesive through the transparent carrier, enabling removal of transparent carrier 102 and leaving structured material 104 on substrate 108.

It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall there between.

What is claimed is:

1. A method for transferring a structured material to a substrate, comprising:
applying a release film to a carrier;
depositing a material on a surface of the release film;
processing the material to form structured material;
coupling the structured material to the substrate;
exposing the release film to reduce adhesion strength between the release film and the carrier; and
removing the carrier and the release film from the structured material.

2. The method of claim 1, further comprising:
applying a second release film to a second carrier;
depositing a second material on a surface of the second release film;
processing the second material to form second structured material;
coupling the second structured material to a second substrate;
exposing the second release film to reduce adhesion strength between the second release film and the second carrier;
removing the second carrier and the second release film from the second structured material; and
coupling the first and second structured materials together to form at least one hermetically sealed chamber between the first and second substrates.

3. The method of claim 1, wherein applying a release film comprises applying a UV release film to a transparent carrier, exposing the release film comprising exposing the UV release film with UV light through the transparent carrier.

4. The method of claim 1, wherein applying a release film comprises applying a polymer adhesive film to a transparent carrier, exposing the release film comprising exposing the polymer adhesive film with laser light through the transparent carrier.

5. The method of claim 1, wherein removing the carrier and the release film comprises ashing to remove the release film.

6. The method of claim 1, wherein depositing the material comprises depositing bond material to the surface.

7. The method of claim 1, wherein processing the material comprises patterning and etching the material to form the structured material.

8. The method of claim 1, wherein coupling the structured material comprises tacking the structured material to the substrate.

9. The method of claim 1, wherein coupling the structured material comprises coupling the structured material to the substrate without contaminating or damaging a device of the substrate.

10. A package, formed by:
applying a release film to a carrier;
depositing a material on a surface of the release film;
processing the material to form a structured material;
coupling the structured material to a substrate having one or more first devices;
exposing the release film to reduce adhesion strength between the release film and the carrier;
removing the carrier and the release film from the structured material; and
coupling a second substrate to the structured material to seal the first devices within one or more hermetically sealed chambers.

11. The package of claim 10, wherein coupling a second substrate comprises coupling a second substrate having one or more second devices such that the first and second devices are sealed within the hermetically sealed chambers.

12. The package of claim 10, the first devices comprising MEMS devices.

13. The package of claim 10, the release film comprising UV release film, the carrier comprising a carrier transparent to UV light.

14. The package of claim 10, the material comprising one of bond material and getter material.

15. The package of claim 10, the release film comprising a polymer adhesive, the carrier comprising a carrier transparent to laser light.

16. The package of claim 10, wherein removing the carrier and the release film comprises removing the carrier from the release film, and ashing away the release film from the structured material.

17. A method for transferring a structured material to a substrate, comprising:
applying a release film to a carrier;
depositing a material on a surface of the release film;
processing the material to form structured material;
coupling the structured material to the substrate;
exposing the release film to reduce adhesion strength of the release film; and
removing the carrier and the release film from the structured material.

18. The method of claim 17, wherein exposing the release film comprises exposing the release film to reduce adhesion strength between the release film and the carrier, removing the carrier and release film comprising removing the carrier from the release film and ashing away the release film from the structured material.

19. The method of claim 17, wherein exposing the release film comprises exposing the release film to reduce adhesion strength between the release film and the structured material, removing the carrier and release film comprising removing the carrier with the release film from the structured material.

20. The method of claim 17, further comprising:
applying a second release film to a second carrier;
depositing a second material on a surface of the second release film;
processing the second material to form second structured material;
coupling the second structured material to a second substrate;
exposing the second release film to reduce adhesion strength between the second release film and the second carrier;
removing the second carrier and the second release film from the second structured material; and
coupling the first and second structured materials together to form at least one hermetically sealed chamber between the first and second substrates.
